(19) United States
(12) Patent Application Publication
(10) Pub. No.: US 2025/0020779 A1
(43) Pub. Date: Jan. 16, 2025

(54) OPTICAL SENSOR WITH INTEGRATED LEADFRAME CAP

(71) Applicant: STMicroelectronics International N.V., Geneva (CH)

(72) Inventors: Dominique Nuyts, St. Egreve (FR); Patrick Laurent, Tullins (FR)

(21) Appl. No.: 18/350,406

(22) Filed: Jul. 11, 2023

(51) Int. Cl. G01S 7/481; G01S 17/08

(52) U.S. Cl. CPC G01S 7/4813; G01S 7/4814; G01S 7/4816; G01S 17/08

(57) ABSTRACT

An electronic device that includes: a substrate including a first contact pad; a cap including a front surface, the cap being attached to a surface of the substrate, the front surface including a first recess and a second recess within the first recess, the cap including a first leadframe embedded within the cap; a first device mounted over the cap and within the second recess; and an optical lens mounted over the cap and the first device, where a first end of the first leadframe is extended out of the cap and electrically connected to the first contact pad, and where a second end of the first leadframe is extended out of the cap at the front surface and electrically connected to the first device.

### TECHNICAL FIELD

The present invention relates generally to a system and method of sensor integration, and, in particular embodiments, to leadframe cap to integrate optical sensors.

### BACKGROUND

Optical sensors are often incorporated in a variety of products such as consumer electronics (e.g., head phones, ear buds, mobile phones, watches, and notebooks) as well as automotive systems and security screening devices. In particular, various types of optical sensors may be used for range finding, depth profiling, 3D imaging, and medical imaging, to name a few. One of the key manufacturing process steps for optical sensors is a packaging step in which individual electronic components for the optical sensor are integrated over a base substrate. A constant trend in manufacturing is reducing packaging cost, while maintaining or improving the sensor performance as well as reducing packaging assembly steps and packaging wiring.

### SUMMARY

In accordance with an embodiment of the present invention, an electronic device that includes: a substrate including a first contact pad; a cap including a front surface, the cap being attached to a surface of the substrate, the front surface including a first recess and a second recess within the first recess, the cap including a first leadframe embedded within the cap; a first device mounted over the cap and within the second recess; and an optical lens mounted over the cap and the first device, where a first end of the first leadframe is extended out of the cap and electrically connected to the first contact pad, and where a second end of the first leadframe is extended out of the cap at the front surface and electrically connected to the first device.

In accordance with an embodiment of the present invention, an electronic device that includes: a substrate including a plurality of contact pads; a cap including a front surface, the cap being attached to a surface of the substrate, the front surface including a upper level, a mezzanine level, and a lower level; a plurality of leadframes embedded within the cap, where one end of each leadframe is extended out of the cap at a bottom side of the cap and electrically connected to one of the plurality of contact pads, and where another end of each leadframe is extend out of the cap at an upper portion of the cap; a first device mounted over the lower level and electrically connected to a first one and a second one of the plurality of leadframes; and an optical lens mounted over the mezzanine level and above the first device.

In accordance with an embodiment of the present invention, a method of manufacturing an electronic device that includes: forming a first leadframe; forming a plastic cap using an injection molding process, the plastic cap having sidewalls and a front surface and enclosing the first leadframe such that one end of the first leadframe is at the front surface and another end of the first leadframe is at a bottom side of one of the sidewalls, the ends of the first leadframe are exposed, the front surface of the plastic cap including a first recess; mounting the plastic cap onto a substrate; and mounting a first device over the front surface of the plastic cap within the first recess.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a perspective view of a conventional design of optical sensor module;

FIG. 2 illustrates a top view of an example leadframe mezzanine cap housing a light source and an optical element for optical sensor module in accordance with various embodiments;

FIG. 3 illustrates a cross sectional view of an example leadframe mezzanine cap housing a light source and an optical element for optical sensor module in accordance with various embodiments;

FIG. 4 illustrates a perspective view of an example leadframe mezzanine cap housing a light source, an optical element, and a reference detector for optical sensor module in accordance with various embodiments;

FIG. 5 illustrates another perspective view of the example leadframe mezzanine cap of FIG. 4 prior to housing the optical element;

FIG. 6 illustrates a perspective view of another example leadframe mezzanine cap housing a light source, an optical element, and a reference detector for optical sensor module in accordance with another embodiment;

FIG. 7 illustrates a perspective view of a leadframe structure of an example leadframe mezzanine cap for optical sensor module in accordance with various embodiments;

FIG. 8 illustrates a top view of a leadframe structure of an example leadframe mezzanine cap for optical sensor module in accordance with various embodiments; and

FIGS. 9A-9B illustrate process flow charts of methods of manufacturing an example leadframe mezzanine cap for optical sensor module in accordance with various embodiments, wherein FIG. 9A illustrates an embodiment, and FIG. 9B illustrates another embodiment.

### DETAILED DESCRIPTION OF ILLUSTRATIVE EMBODIMENTS

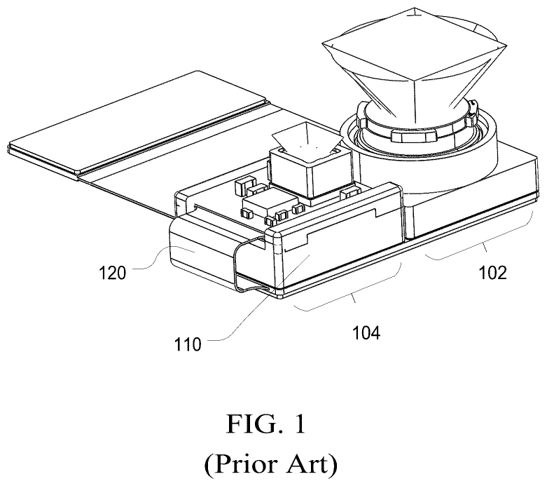

This application relates to a system and method of sensor integration, more particularly to introduction of a leadframe mezzanine cap to an optical sensor module. For certain sensor applications (e.g., time-of-flight proximity sensor), the optical sensor module may generally comprise a light source (e.g., a laser) and an optical detector, both of which may be mounted and packaged on a substrate. The light source emits light, and a portion of the emitted light is reflected from an object in the environment to be sensed and picked up by the optical detector. To accommodate for different focal lengths of the transmitter and receiver and to avoid undesired crosstalk between the two elements, the light source may be positioned in the sensor module at a higher level than the optical detector on the substrate. This design may be realized by, for example, inserting a spacer block below the light source and provide electrical connections with flat flexible cables (FFCs) as illustrated in FIG. 1. However, such a design often requires a large footprint for the FFCs and its manufacturing process may be complicated. Therefore, a new design for the optical sensor module without using FFCs may be desired.

In various embodiments of this disclosure, a leadframe mezzanine cap is used for optical sensor module (e.g., time-of-fight proximity sensor), where the light source may be mounted over this cap such that it is at a higher level than the optical detector. In this disclosure, the cap may be referred to as leadframe mezzanine cap because it comprises a leadframe structure embedded within the body of the cap, and also the cap has a mezzanine level (i.e., a recessed surface that is lower than an uppermost surface) to house the light source and optionally other components (e.g., optical lens). The electrical connections for the light source may advantageously be provided by the leadframe embedded within the cap, thereby eliminating the need for at least some of the FFCs in conventional designs. As a result, this new cap design may allow reducing the footprint for the optical sensor module and simplify the manufacturing process. Further, in certain embodiments, the optical sensor module may comprise other elements (e.g., optical lens and reference detector) and the leadframe structure, comprising multiple leadframes, may also be electrically connected to them individually. The leadframe mezzanine cap may be designed to securely mount these other elements near the top of the leadframe mezzanine cap.

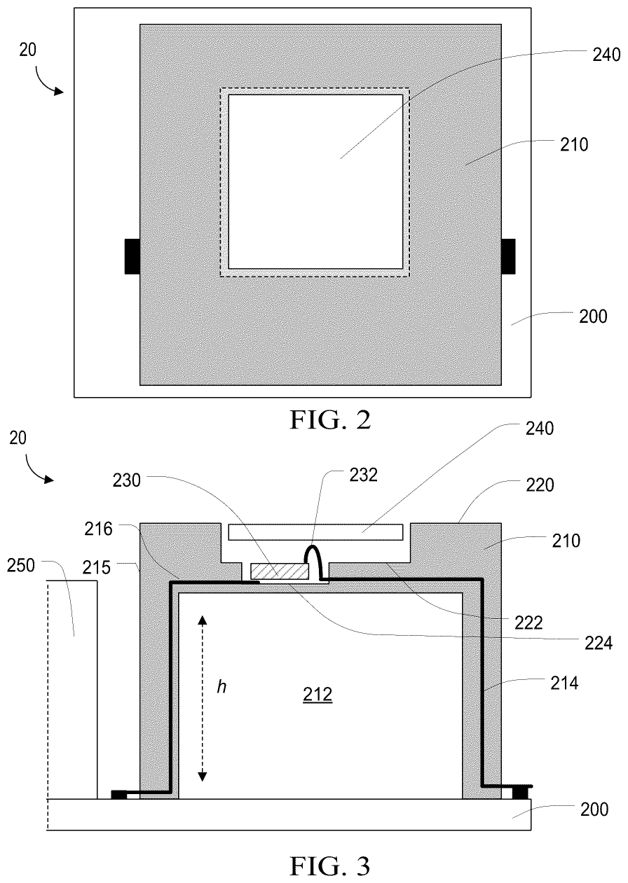

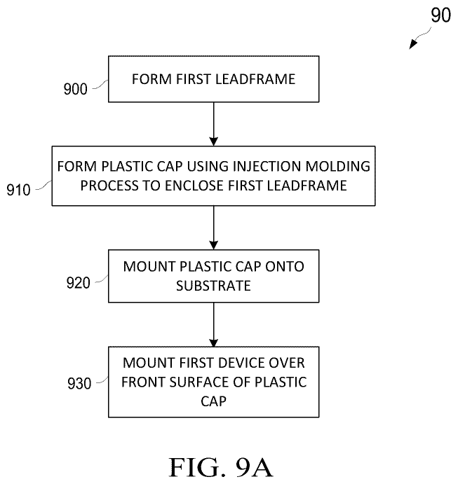

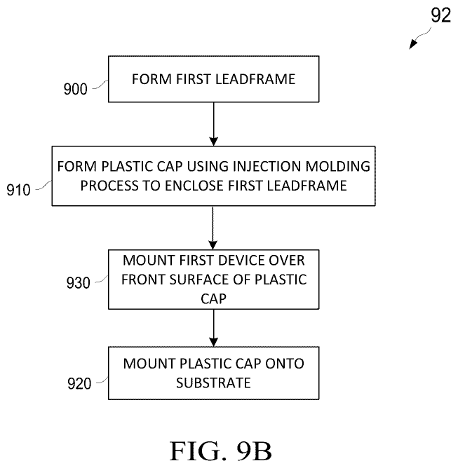

In the following, a conventional design for an optical sensor module with a light source is first described referring to FIG. 1. The design of a leadframe mezzanine cap integrated to an optical sensor module is then described in accordance with various embodiments referring to FIGS. 2-8. Example process flow diagrams to manufacture a leadframe mezzanine cap is illustrated in FIGS. 9A-9B. All figures in this disclosure are drawn for illustration purpose only and not to scale, including the aspect ratios of features. Although the description below in this disclosure is mainly for the leadframe mezzanine cap and the light source mounted over the cap, the optical sensor module may comprise various other components (e.g., optical detector) on the same substrate or elsewhere.

FIG. 1 illustrates a perspective view of a conventional design of optical sensor module.

A conventional design of optical sensor module is briefly described below. The optical sensor module may have two sections: an optical sensor section 102 and a light source section 104. These two sections may often have different focal lengths, and there is a risk of crosstalk between different optical components. To compensate this difference in focal length as well as minimize the crosstalk, elements within the light source section 104 may be lifted by a spacer block 110, and flat flexible cables (FFCs) 120 may be used for electrical connections. In addition, matching the top planes of the light source section 104 and the optical sensor section 102 may also be desired for the ease of device component integration. Drawbacks of this design include a large footprint for the FFCs 120, a complicated manufacturing process and increased cost, and dead space due to the spacer block 110.

FIGS. 2 and 3 illustrates an example leadframe mezzanine cap 210 housing a light source 230 and an optical element 240 for optical sensor module in accordance with various embodiments, wherein FIG. 2 illustrates a top view and FIG. 3 illustrates a cross sectional view.

In various embodiments, the leadframe mezzanine cap 210 is mounted over a substrate 200 as a part of an optical sensor module 20. It should be noted that only a portion of the optical sensor module 20 is illustrated in FIGS. 2 and 3, and other components (e.g., optical detector) may be present in various embodiments over the substrate 200 or elsewhere. The substrate 200 may comprise a printed circuit board (PCB) in various embodiments. In one embodiment, the substrate 200 may be a PCB made of FR-4 glass-reinforced epoxy laminate. Only a portion of the substrate 200 is illustrated in FIGS. 2 and 3. Various electrical components for the optical sensor module 20 may be mounted over the substrate 200 and electrically connected to each other, for example, using wire bonding.

In various embodiments, the leadframe mezzanine cap 210 may have a square or rectangular shape as seen in the top view of FIG. 2, but in other embodiments, it may have any other reasonable shape. The leadframe mezzanine cap 210 may comprise sidewalls 215 and a front surface 220 as seen in the cross sectional view of FIG. 3, such that they define a cavity 212 below the front surface 220. In this disclosure, “front” side or surface and “bottom” side or surface of the leadframe mezzanine cap 210 are used only to describe a relative position to a substrate to which the leadframe mezzanine cap 210 may be mounted, with the bottom side facing toward the substrate and the front side facing away from the substrate. Sidewalls are any side or surfaces other than the front or bottom sides or surfaces, and may or may not be distinctly present in the leadframe mezzanine cap 210 (e.g., they may not be clearly distinguishable if the cap has an oval shape). Accordingly, it should be noted that, depending on the mounting direction and configuration of the optical sensor module, any side of the leadframe mezzanine cap 210 may be considered to be the front surface 220 and not limited to the illustrated embodiments in FIGS. 2-8. In various embodiments, the cavity 212 defined by the leadframe mezzanine cap 210 may have a height h relative to a front surface of the substrate 200, and in one embodiment, the height h may be between 0.1 mm and 10 mm. The height h may be selected to lift the positioning of one or more elements (e.g., a light source) mounted over the leadframe mezzanine cap 210. In one embodiment, one of the elements may be positioned at between 0.1 mm and 10 mm above the front surface of the substrate 200.

Although not specifically illustrated in FIG. 2, the cavity 212 may be further separated into two or more spaces separated by one or more partition walls. The partition walls may be an inner part of the leadframe mezzanine cap 210, and may provide additional structural support for the front surface or optical isolation within the cavity 212.

The leadframe mezzanine cap 210 may receive a light source 230 over the front surface 220. The front surface 220 may comprise a recessed surface such that one or more elements may be mounted such that a final state of the optical sensor module 20 may have a relatively flat surface. In certain embodiments, as illustrated in FIG. 3, the front surface 220 may further comprise a first recessed surface 222 (mezzanine level) and a second recessed surface 224 (lower level), where the second recessed surface 224 is lower and within the first recessed surface 222. In one or more embodiments, the light source 230 may be housed within the area of the second recessed surface 224, and an optical element 240 may be positioned above the light source 230 and housed within the area of the first and second recessed surfaces 222 and 224.

As illustrated in FIG. 3, the optical element 240 may be positioned above the light source 230 and covers the entirety of the light source 230. Accordingly, only a front surface of the optical element 240 is visible in FIG. 2.

Although FIG. 3 illustrates an embodiment of a leadframe mezzanine cap having two recesses (i.e., the mezzanine level and lower level), in other embodiments, it is possible to have an extra recess. For example, the leadframe mezzanine cap 210 may comprise three recesses (e.g., high, middle, lower levels) or more. The light source 230 may be disposed at the lower level, the optical element 240 may be disposed at the middle level, and an optical baffle may be disposed at the high level in one embodiment. The optical baffle may protect wire bonds connected to the optical element 240. The optical baffle may also comprise an aperture in certain embodiments.

In various embodiments, the light source 230 may comprise a vertical-cavity surface-emitting laser (VCSEL) for the optical sensor module 20, and the optical element 240 may comprise an optical lens which the light (e.g., a laser from the VCSEL) passes through. In other embodiments, the light source 230 may comprise a light emitting diode (LED) or an edge emitting laser (EEL). In certain embodiments, the optical element 240 may further comprise a light filter. Although a single light source and a single optical element are illustrated in FIGS. 2 and 3, the leadframe mezzanine cap 210 may house multiple light sources or optical elements. For example, in one embodiment, an array of VCSEL may be used. The number of recesses and footprint for each level of the leadframe mezzanine cap 210 may be selected according to the design of the optical sensor module 20.

In one embodiment, the entirety of the optical element 240 may be positioned within the recessed area of the front surface 220 and no portion of the optical element 240 protrudes from the leadframe mezzanine cap 210. In another embodiment, a top portion of the optical element 240 may protrude from the leadframe mezzanine cap 210.

In various embodiments, the leadframe mezzanine cap 210 may further comprise a leadframe structure to provide electrical connections for various components (e.g., the light source 230). In FIG. 2, two leadframes (a first leadframe 214 and a second leadframe 216) are illustrated as an example, but in other embodiments, any number of leadframes may be possible. In certain embodiments, the leadframe structure is mostly embedded within the body of the leadframe mezzanine cap 210 except ends of each leadframe for electrical connections. In one or more embodiments, some additional portions of the leadframe structure other than their ends may also be exposed, which may be useful in preventing deformation during the fabrication of the leadframe mezzanine cap 210 (e.g., an injection molding process). The exposed portion of the leadframe structure may advantageously be used to directly attach a heat sink on the inside of the leadframe structure within the cavity 212.

As illustrated in FIG. 2, one end (lower end) of the first leadframe 214 may be extended out of the leadframe mezzanine cap 210 at its bottom side and electrically connected to a contact pad on the substrate 200. Although not specifically illustrated, the lower end of the first leadframe 214 may be connected to the contact pad without protruding from the outline of the leadframe mezzanine cap 210 in the top view.

The other end (upper end) of the first leadframe 214 may be extended out of the leadframe mezzanine cap 210 inside the recessed area of the front surface 220 and electrically connected to the light source 230. In one embodiment, as illustrated in FIG. 2, a bond wire 232 may be used to connect this upper end of the first leadframe 214 to a top portion of the light source 230.

Similarly, one end (lower end) of the second leadframe 216 may be extended out of the leadframe mezzanine cap 210 at its bottom side and electrically connected to a contact pad on the substrate 200. In certain embodiments, the lower end may not protrude from the outline of the leadframe mezzanine cap 210 in the top view.

The other end (upper end) of the second leadframe 216 may be extended out of the leadframe mezzanine cap 210 inside the recessed area of the front surface 220 (e.g., near the second recessed surface 224) and electrically connected to the light source 230. As illustrated in FIG. 2, this upper end of the second leadframe 216 may be directly connected to a bottom portion of the light source 230 without wire bonding in one embodiment, but in other embodiments, a bond wire or other methods may be used. In one embodiment, the electrical connection between the second leadframe 216 and the light source 230 may be made at a top portion of the light source 230. The type and configuration of electrical connections between the light source 230 and corresponding leadframes are not limited to those illustrated in FIG. 2 and may be selected according to specific applications and design of the optical sensor module 20.

In various embodiments, the body of leadframe mezzanine cap 210 may comprise a plastic material and the leadframe structure may comprise an electrically conductive material such as copper. The leadframe mezzanine cap 210 may be manufactured using an injection molding process. For example, in an example manufacturing process, a leadframe structure may be formed first, and a thermoplastic material may be molded into a target shape for a cap that encloses the leadframe structure using injection molding (e.g., overmolding). In certain embodiments, more than one separate leadframes may be formed in multitudes or individually, aligned with each other according to the target configuration, and overmolded.

The use of plastics for the body of the leadframe mezzanine cap 210 may advantageously makes the cap opaque, thereby the cavity 212 and the light source 230 may be optically isolated. This is advantageous in avoiding any light from the light source enters the cavity 212 where other optically sensitive elements may be present. The material for the body of leadframe mezzanine cap 210 is also electrically non-conductive.

In various embodiments, the optical sensor module 40 is a part of a time-of-flight sensor, and may further comprise a detector assembly 250 over the substrate 200. The detector assembly 250 may comprise various elements necessary for optical detection of a portion of the emitted light from the light source 230. For example, the detector assembly 250 may comprise single photo avalanche diode (SPAD) arrays as a detector system. Further, the detector assembly 250 may also comprise a cap to house the detector over the substrate 200. In one embodiment, leadframe mezzanine cap 210 may be made large enough to house the detector assembly 250, where the detector assembly 250 and the cavity 212 may be separated by a partition wall inside the leadframe mezzanine cap 210.

FIG. 4 illustrates a perspective view of an example leadframe mezzanine cap 410 housing a light source 230 and an optical element 240 for an optical sensor module 40 in accordance with various embodiments.

Referring to FIG. 4, a modified design for the leadframe mezzanine cap 410 is further described in accordance with certain embodiments. The light source 230 and the optical element 240 may be identical to those described in FIGS. 2 and 3. As illustrated in FIG. 4, the leadframe mezzanine cap 410 in these embodiments may have sidewalls 415 with steps, in contrast to the sidewalls 215 that are vertically straight from top to bottom in FIG. 3. The sidewalls steps may be designed such that a top portion of the leadframe mezzanine cap 410 has a footprint smaller than that of a bottom portion. In FIG. 4, the sidewalls 415 have two steps on at least one side of the leadframe mezzanine cap 410, but the sidewalls can have various other shapes and designs in other embodiments. Further, the sidewall thickness of the leadframe mezzanine cap 410 may be relatively constant. The shape of the leadframe mezzanine cap 410 may be adjusted accordingly to requirements in various sensor applications, for example, the size and desired location of various components to be mounted (e.g., the light source 230 and the optical element 240) as well as the cavity inside the leadframe mezzanine cap 410. This flexibility for designing and manufacturing the leadframe mezzanine cap 410 may advantageously help minimizing the use of plastic and/or the size of the optical element 240 as well as maximizing the volume of the cavity.

The leadframe mezzanine cap 410 in FIG. 4 has a front surface 420, which further comprises three recessed surfaces: a first recessed surface 422, a second recessed surface 424, and a third recessed surface 426 in order of height position, with the third recessed surface 426 being the lowest in FIG. 4. The light source 230 may be disposed on the third recessed surface 426 and the optical element 240 may be disposed on the second recessed surface 424. An optical baffle (not shown) may be disposed on the first recessed surface 422.

Still referring to FIG. 4, the leadframe mezzanine cap 410 may comprise two additional leadframes that form safety trace connections 412 for the optical element 240. In certain embodiments, these safety trace connections 412 may be desired because they can be used for checking the proper installation and presence of the optical element 240. These additional leadframes may also be embedded within the body of the leadframe mezzanine cap 410 except their ends. For example, one end (lower end) of an additional leadframe may be extended out of the leadframe mezzanine cap 410 at its bottom side and electrically connected to a contact pad on the substrate 200. The other end (upper end) of the second leadframe 216 may be extended out of the leadframe mezzanine cap 410 inside the recessed area of the top surface and electrically connected to the optical element 240.

As previously illustrated in FIG. 1, conventional designs may use a spacer block for mounting a light source, and this spacer block may have a substantial footprint on the substrate. In contrast, the use of the leadframe mezzanine cap 410 may occupy only a small fraction of the front surface of the substrate 200 and leaves room for mounting various components. Accordingly, in various embodiments, within the cavity defined by the leadframe mezzanine cap 410, the optical sensor module 40 may further comprise additional electrical components 450 mounted over the substrate 200. Examples of the additional electrical components 450 include but are not limited to a passive element (e.g., inductors, capacitors, and resistors), laser driver, and electrically erasable programmable read-only memory (EEPROM).

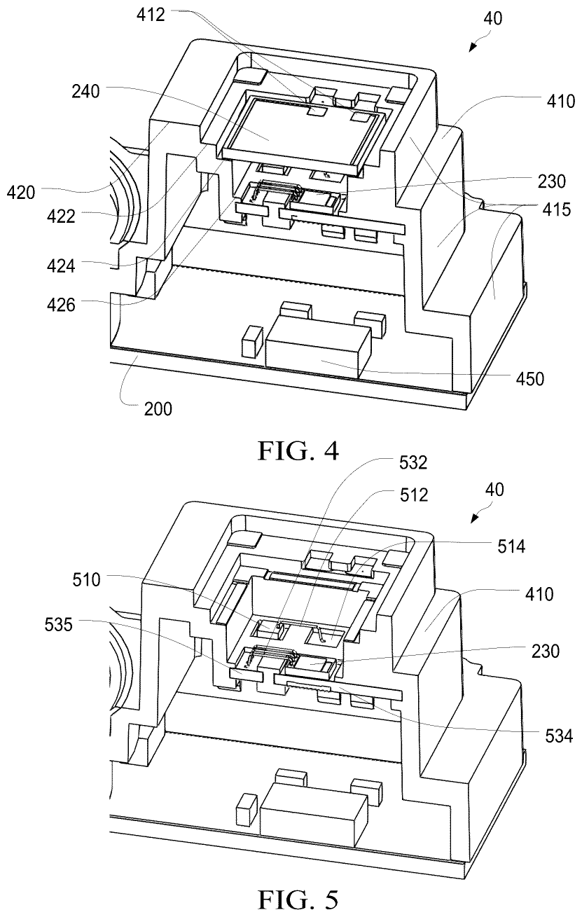

FIG. 5 illustrates another perspective view of the example leadframe mezzanine cap 410 of FIG. 4 prior to housing the optical element 240. The optical element 240 is not illustrated in FIG. 5 in order to illustrate other elements below it.

In various embodiments, in addition to the light source 230 and the optical element 240, the leadframe mezzanine cap 410 may also receive an additional component, for example, a reference detector 510. In certain embodiments, the reference detector may comprise a photodiode configured to optically sense a status of the light source 230. Having a reference detector advantageously enables monitoring and checking the proper performance of the optical sensor module 40, in particular the light source 230. The detection by the reference detector may also be used for time-of-flight analysis. In one or more embodiments, the reference detector 510 may comprise single photo avalanche diode (SPAD) arrays. In certain embodiments, the reference detector 510 or other components may be mounted over the leadframe mezzanine cap 410 within the recessed are of the front surface 420, for example, at the same level as the light source 230. In other embodiments, the reference detector 510 may be positioned at any level below the optical element 240. In one embodiment, the reference detector 510 may be mounted on the substrate 200. In various embodiments, the leadframe mezzanine cap 410 may comprise one or more additional leadframes that provides electrical connections for the reference detector 510 in FIG. 5. In one or more embodiments, one or more of the leadframes connected to the light source 230 may also be connected to the reference detector 510, minimizing the number of additional leadframes for the reference detector 510.

In certain embodiments, as illustrated in FIG. 5, a bond wire 512 may be used to connect an upper end of an additional leadframe, which can be a reference detector cathode leadframe 514, to a top portion of the reference detector 510. In various embodiments, more than one bond wire may be used for electrical connection with the reference detector 510. An upper end of another additional leadframe, which can be a reference detector anode leadframe (not visible in FIG. 5) may be directly connected to a bottom portion of the reference detector 510 without wire bonding in one embodiment, but in other embodiments, a bond wire or other methods may be used. Further, in one embodiment, both cathode and anode of the reference detector 510 may be located at the top portion and may be connected to corresponding leadframes using bond wires.

Still referring to FIG. 5, one or more bond wires 532 may be used to connect a light source cathode leadframe 535 to a top portion of the light source 230, while a light source anode leadframe 534 may be directed connected to a bottom portion of the light source 230 without wire bonding in one embodiment, but in other embodiments, a bond wire or other methods may be used.

The type and configuration of electrical connections between various electrical components (e.g., the reference detector 510, the light source 230, and the optical element 240) and corresponding leadframes are not limited to those illustrated in FIGS. 4-5 and may be selected according to specific applications and design of the optical sensor module 40.

Although not specifically illustrated in FIGS. 4-5, in other embodiments, the electrical components as above may be positioned differently, and the front surface 420 may comprise three or more recessed surfaces. In one embodiment, the light source 230, the reference detector 510, the optical element 240, and an optical baffle may be positioned at four different height levels, from bottom to top. The optical element 240 may accordingly cover both the light source 230 and the reference detector 510, and the optical baffle may cover at least a portion of the optical element 240 and wire bonds for the optical element 240.

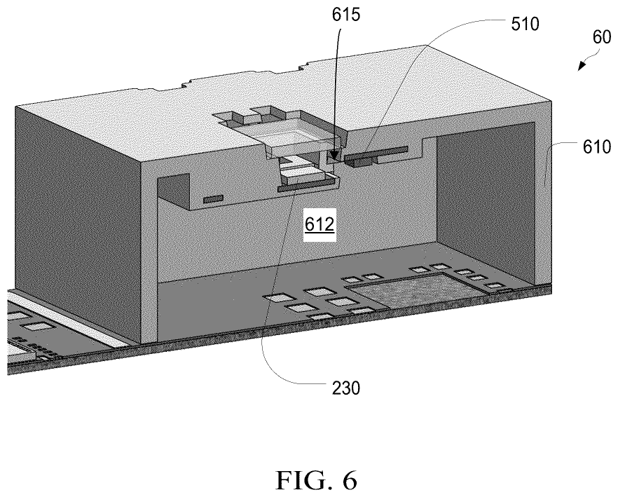

FIG. 6 illustrates a perspective view of another example leadframe mezzanine cap 610 housing a light source, an optical element, and a reference detector for optical sensor module in accordance with another embodiment.

In prior embodiments illustrated in FIGS. 4-5, the reference detector 510 and the light source 230 are mounted at the same level within the recessed area of the leadframe mezzanine cap 410 and both of them are faced upwards. In other embodiments, the reference detector 510 may be positioned differently but still within the recessed area of the leadframe mezzanine cap 410. Such a configuration may advantageously help reducing the size of the optical element and thus the manufacturing cost for optical sensor module.

In FIG. 6, the recessed area of the leadframe mezzanine cap 610 may have an opening 615 that connects the recessed area and a cavity 612 within the leadframe mezzanine cap 610. This opening 615 may allow a portion of the light from the light source 230 that reflects back at the surface of the optical element 240 to enter the cavity. Accordingly, it is possible to install a reference detector 510 inside the cavity 612. In one or more embodiments, as illustrated in FIG. 6, the reference detector 510 may be mounted on an inner surface of the leadframe mezzanine cap 610 and faced downwards. Accordingly, additional leadframes for the reference detector 510 may be arranged to have their upper ends extended out inside the cavity 612 such that they may be connected to the reference detector 510 easily.

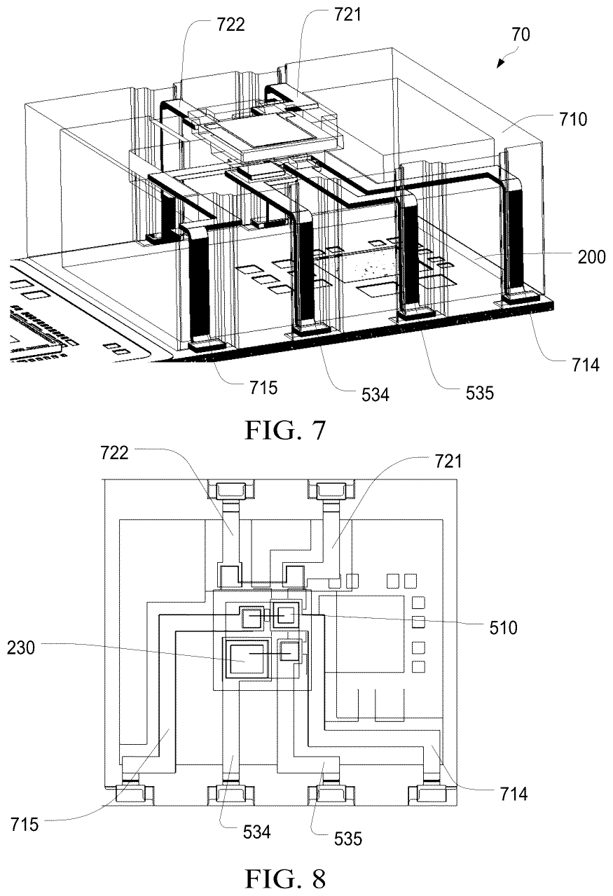

FIG. 7 illustrates a perspective view of a leadframe structure of an example leadframe mezzanine cap 710 for an optical sensor module 70 in accordance with various embodiments. FIG. 8 illustrates a top view of the leadframe structure of FIG. 7.

As described previously, in various embodiments, the leadframe structure of the leadframe mezzanine cap may comprise any number of leadframes and these leadframes may be integrated as a part of the leadframe mezzanine cap. In FIGS. 7 and 8, an example for a leadframe mezzanine cap 710 having six leadframes is illustrated. For illustration purpose, the body of the leadframe mezzanine cap 710 (e.g., a plastic body) is illustrated only with line for its framework to make the leadframes that are embedded within the body visible. In FIGS. 7 and 8, the leadframe mezzanine cap 710 has a light source anode leadframe 534, a light source cathode leadframe 535, a reference detector anode leadframe 714, a reference detector cathode leadframe 715, a first safety trace leadframe 721, and a second safety trace leadframe 722.

Each leadframe may be embedded within the body of the leadframe mezzanine cap 710 except its ends as previously described. In various embodiments, each leadframe may be designed to provide electrical connections between a component mounted at a lower level and another component mounted at a higher level (e.g., at any level near the top surface of the leadframe mezzanine cap 710). Accordingly, one end (lower end) of each leadframe may be electrically connected to a contact pad on a substrate 200. The other end (upper end) of each leadframe may be electrically connected to a component mounted over the leadframe mezzanine cap 710.

In FIGS. 7 and 8, four leadframes (the light source anode leadframe 534, the light source cathode leadframe 535, the reference detector anode leadframe 714, and the reference detector cathode leadframe 715) are connected on one end of the substrate 200 and the other two leadframes (the first safety trace leadframe 721 and the second safety trace leadframe 722) are connected on the opposite end of the substrate 200 in accordance with one embodiment. In alternate embodiments, the leadframes may have connection points to the substrate 200 different from those illustrated in FIGS. 7 and 8, depending on the available footprint on the substrate 200 and the cap design as well as the positions of the components over the leadframe mezzanine cap.

Further, the upper end of each leadframe may be positioned according to the position of the corresponding component to be connected. In various embodiments, since the optical element may be positioned above the light source and the reference detector, the two leadframes (the first safety trace leadframe 721 and the second safety trace leadframe 722) for the optical element may have upper ends positioned higher than those for the other four leadframes (the light source anode leadframe 534, the light source cathode leadframe 535, the reference detector anode leadframe 714, and the reference detector cathode leadframe 715). The set of the light source anode leadframe 534 and the light source cathode leadframe 535 may have upper ends positioned at the same level as those of the set of the reference detector anode leadframe 714 and the reference detector cathode leadframe 715 in certain embodiments, but in other embodiments they may be at a different level in view of the optical configuration of the light source and the reference detector.

While six leadframes are illustrated in FIGS. 7 and 8, in certain embodiments, some of them may be optional and omitted from an optical sensor module. In one embodiment, the optical element may be installed without a safety trace feature and thereby the first safety trace leadframe 721 and the second safety trace leadframe 722 in FIGS. 7 and 8 may be omitted. In another embodiment, the reference detector may be optional, and thereby the reference detector anode leadframe 714 and the reference detector cathode leadframe 715 in FIGS. 7 and 8 may be omitted.

FIGS. 9A-9B illustrate process flow charts of methods of manufacturing an example leadframe mezzanine cap for optical sensor module in accordance with various embodiments.

In FIG. 9A, a process flow 90 starts with forming a first leadframe (block 900), followed by forming a plastic cap using an injection molding process, for example with a thermoplastic material (block 910) such that the plastic cap can have sidewalls and a front surface and enclose the first leadframe, where one end of the first leadframe is at the front surface, another end of the first leadframe is at a bottom side of one of the sidewalls, the ends of the first leadframe are exposed, and the top surface of the plastic cap comprises a first recess. Subsequently, the plastic cap may be mounted onto a substrate (block 920), and then a first device (e.g., a light source such as a vertical-cavity surface-emitting laser, VCSEL) may be mounted over the top surface of the plastic cap within the first recess (block 930).

In certain embodiments, the substrate may comprise a contact pad and solder, and mounting the plastic cap onto the substrate can also directly form electrical connections between the first device to the one end of the first leadframe. In other embodiments, the electrical connections may be formed separately after mounting the plastic cap by, for example, solder jetting.

In FIG. 9B, another process flow 92 starts with the same steps of forming a first leadframe (block 900) and a plastic cap (block 910) as described above. After these steps, the first device may be mounted over the top surface of the plastic cap first (block 930), and then the plastic cap carrying the first device may be mounted onto a substrate (block 920).

The use of injection molding (e.g., overmolding) allows the manufacturing of the leadframe mezzanine cap to be flexible and any reasonable design and shape can be manufactured relatively easily without substantial additional cost. In addition, it is also possible that an injection molding process may be used to manufacture multiple plastic parts with or without a portion of a leadframe structure embedded inside, and then assembling these plastic parts to form a final leadframe mezzanine cap.

The leadframe mezzanine cap described as above in various embodiments may offer various advantages over the conventional methods of sensor integration. First, the leadframe mezzanine cap can lift the position of a light source and an optical element relative to a detector, minimizing the risk of crosstalk. Second, with embedding the leadframe within this cap, it is possible to remove a spacer block and at least a portion of flat flexible cables (FFCs) often used in the conventional design. This may advantageously reduce the manufacturing cost and free up some footprint on the substrate. The freed space on the substrate can be used for mounting other components. Third, the addition of a leadframe mezzanine cap can be possible with minimal additional cost. This is because, in certain optical sensor applications where a strong laser may be used, an enclosure cap that covers the optical element (e.g., optical lens) may already be required to limit the light path for safety. As the leadframe mezzanine cap may be realized by modifying the already required enclosure cap, it may be introduced to the optical sensor module without a completely new component.

Example embodiments of the invention are summarized here. Other embodiments can also be understood from the entirety of the specification as well as the claims filed herein.

Example 1. An electronic device that includes: a substrate including a first contact pad; a cap including a front surface, the cap being attached to a surface of the substrate, the front surface including a first recess and a second recess within the first recess, the cap including a first leadframe embedded within the cap; a first device mounted over the cap and within the second recess; and an optical lens mounted over the cap and the first device, where a first end of the first leadframe is extended out of the cap and electrically connected to the first contact pad, and where a second end of the first leadframe is extended out of the cap at the front surface and electrically connected to the first device.

Example 2. The electronic device of example 1, where the first device includes a vertical-cavity surface-emitting laser (VCSEL).

Example 3. The electronic device of one of examples 1 or 2, where an entirety of the optical lens is placed within the first recess.

Example 4. The electronic device of one of examples 1 to 3, further including a second device disposed over the cap, where the cap further includes a second leadframe embedded within the cap, where a first end of the second leadframe is extended out of the cap and electrically connected to a second contact pad of the substrate, and where a second end of the second leadframe is extended out of the cap at the front surface and electrically connected to the second device.

Example 5. The electronic device of one of examples 1 to 4, where the first device is a light source to emit a light, and where the second device includes a photodiode configured to optically sense a status of the first device by detecting a portion of the light emitted from the light source.

Example 6. The electronic device of one of examples 1 to 5, where the cap further includes a third leadframe embedded within the cap, where a first end of the third leadframe is extended out of the cap and electrically connected to a third contact pad of the substrate, and where a second end of the third leadframe is extended out of the cap at the front surface and electrically connected to the optical lens.

Example 7. An electronic device that includes: a substrate including a plurality of contact pads; a cap including a front surface, the cap being attached to a surface of the substrate, the front surface including a upper level, a mezzanine level, and a lower level; a plurality of leadframes embedded within the cap, where one end of each leadframe is extended out of the cap at a bottom side of the cap and electrically connected to one of the plurality of contact pads, and where another end of each leadframe is extend out of the cap at an upper portion of the cap; a first device mounted over the lower level and electrically connected to a first one and a second one of the plurality of leadframes; and an optical lens mounted over the mezzanine level and above the first device.

Example 8. The electronic device of example 7, further including a wire connecting the first device and the first one of the plurality of leadframes, where the first device is directly mounted on an end of the second one of the plurality of leadframes to provide electrical connection.

Example 9. The electronic device of one of examples 7 or 8, further including a second device mounted over the lower level and electrically connected to a third one and a fourth one of the plurality of leadframes.

Example 10. The electronic device of one of examples 7 to 9, where the optical lens is electrically connected to a fifth one and a sixth one of the plurality of leadframes.

Example 11. The electronic device of one of examples 7 to 10, where the front surface of the cap includes an opening, further including a second device mounted inside the cap at the upper portion of the cap and electrically connected to a third one and a fourth one of the plurality of leadframes.

Example 12. The electronic device of one of examples 7 to 11, where the first device includes a vertical-cavity surface-emitting laser (VCSEL) facing upwards, and where the second device includes a photodiode facing downwards and being configured to optically sense a status of the VCSEL.

Example 13. The electronic device of one of examples 7 to 12, where the first device is positioned at between 0.1 mm and 10 mm above the surface of the substrate.

Example 14. The electronic device of one of examples 7 to 13 further including an optical sensor mounted over the surface of the substrate, the optical sensor being enclosed within the cap.

Example 15. A method of manufacturing an electronic device that includes: forming a first leadframe; forming a plastic cap using an injection molding process, the plastic cap having sidewalls and a front surface and enclosing the first leadframe such that one end of the first leadframe is at the front surface and another end of the first leadframe is at a bottom side of one of the sidewalls, the ends of the first leadframe are exposed, the front surface of the plastic cap including a first recess; mounting the plastic cap onto a substrate; and mounting a first device over the front surface of the plastic cap within the first recess.

Example 16. The method of example 15, further including electrically connecting the first device to the one end of the first leadframe.

Example 17. The method of one of examples 15 or 16, where the front surface of the plastic cap further includes a second recess larger than the first recess, the first recess being within the second recess, the method further including mounting an optical lens over the front surface of the plastic cap within the second recess, the optical lens being disposed over the first device.

Example 18. The method of one of examples 15 to 17, further including: forming a second leadframe, where the plastic cap is formed to enclose the second leadframe such that one end of the second leadframe is at the front surface and another end of the second leadframe is at the bottom side of one of the sidewalls, the ends of the second leadframe are exposed; and electrically connecting the first device to the one end of the second leadframe.

Example 19. The method of one of examples 15 to 18, where mounting the plastic cap onto the substrate forms a cavity defined by the plastic cap and the substrate, the cavity being optically isolated from the first device.

Example 20. The method of one of examples 15 to 19, further including mounting another electrical component over the substrate, where the another electrical component is enclosed by the plastic cap after mounting the plastic cap onto the substrate.

Example 21. The method of one of examples 15 to 20, where the first device includes a vertical-cavity surface-emitting laser (VCSEL) facing upwards, the method further including mounting a second device onto the plastic cap, the second device including a photodiode configured to optically sense a status of the VCSEL.

Example 22. The method of one of examples 15 to 21, where the first device includes a laser, the method further including mounting an optical sensor over the substrate.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. As an illustration, the embodiments described in FIGS. 1-9B may be combined with each other in further embodiments. It is therefore intended that the appended claims encompass any such modifications or embodiments.

What is claimed is:

1. An electronic device comprising:
a substrate comprising a first contact pad;
a cap comprising a front surface, the cap being attached to a surface of the substrate, the front surface comprising a first recess and a second recess within the first recess, the cap comprising a first leadframe embedded within the cap;
a first device mounted over the cap and within the second recess; and
an optical lens mounted over the cap and the first device,
wherein a first end of the first leadframe is extended out of the cap and electrically connected to the first contact pad, and
wherein a second end of the first leadframe is extended out of the cap at the front surface and electrically connected to the first device.

2. The electronic device of claim 1, wherein the first device comprises a vertical-cavity surface-emitting laser (VCSEL).

3. The electronic device of claim 1, wherein an entirety of the optical lens is placed within the first recess.

4. The electronic device of claim 1, further comprising a second device disposed over the cap,
wherein the cap further comprises a second leadframe embedded within the cap,
wherein a first end of the second leadframe is extended out of the cap and electrically connected to a second contact pad of the substrate, and
wherein a second end of the second leadframe is extended out of the cap at the front surface and electrically connected to the second device.

5. The electronic device of claim 4, wherein the first device is a light source to emit a light, and wherein the second device comprises a photodiode configured to optically sense a status of the first device by detecting a portion of the light emitted from the light source.

6. The electronic device of claim 1, wherein the cap further comprises a third leadframe embedded within the cap,
wherein a first end of the third leadframe is extended out of the cap and electrically connected to a third contact pad of the substrate, and
wherein a second end of the third leadframe is extended out of the cap at the front surface and electrically connected to the optical lens.

7. An electronic device comprising:
a substrate comprising a plurality of contact pads;
a cap comprising a front surface, the cap being attached to a surface of the substrate, the front surface comprising a upper level, a mezzanine level, and a lower level;
a plurality of leadframes embedded within the cap, wherein one end of each leadframe is extended out of the cap at a bottom side of the cap and electrically connected to one of the plurality of contact pads, and wherein another end of each leadframe is extend out of the cap at an upper portion of the cap;
a first device mounted over the lower level and electrically connected to a first one and a second one of the plurality of leadframes; and
an optical lens mounted over the mezzanine level and above the first device.

8. The electronic device of claim 7, further comprising a wire connecting the first device and the first one of the plurality of leadframes, wherein the first device is directly mounted on an end of the second one of the plurality of leadframes to provide electrical connection.

9. The electronic device of claim 7, further comprising a second device mounted over the lower level and electrically connected to a third one and a fourth one of the plurality of leadframes.

10. The electronic device of claim 7, wherein the optical lens is electrically connected to a fifth one and a sixth one of the plurality of leadframes.

11. The electronic device of claim 7, wherein the front surface of the cap comprises an opening, further comprising a second device mounted inside the cap at the upper portion of the cap and electrically connected to a third one and a fourth one of the plurality of leadframes.

12. The electronic device of claim 11, wherein the first device comprises a vertical-cavity surface-emitting laser (VCSEL) facing upwards, and wherein the second device comprises a photodiode facing downwards and being configured to optically sense a status of the VCSEL.

13. The electronic device of claim 7, wherein the first device is positioned at between 0.1 mm and 10 mm above the surface of the substrate.

14. The electronic device of claim 7 further comprising an optical sensor mounted over the surface of the substrate, the optical sensor being enclosed within the cap.

15. A method of manufacturing an electronic device, the method comprising:
forming a first leadframe;
forming a plastic cap using an injection molding process, the plastic cap having sidewalls and a front surface and enclosing the first leadframe such that one end of the first leadframe is at the front surface and another end of the first leadframe is at a bottom side of one of the sidewalls, the ends of the first leadframe are exposed, the front surface of the plastic cap comprising a first recess;
mounting the plastic cap onto a substrate; and
mounting a first device over the front surface of the plastic cap within the first recess.

16. The method of claim 15, further comprising electrically connecting the first device to the one end of the first leadframe.

17. The method of claim 15, wherein the front surface of the plastic cap further comprises a second recess larger than the first recess, the first recess being within the second recess, the method further comprising mounting an optical lens over the front surface of the plastic cap within the second recess, the optical lens being disposed over the first device.

18. The method of claim 15, further comprising:
forming a second leadframe, wherein the plastic cap is formed to enclose the second leadframe such that one end of the second leadframe is at the front surface and another end of the second leadframe is at the bottom side of one of the sidewalls, the ends of the second leadframe are exposed; and
electrically connecting the first device to the one end of the second leadframe.

19. The method of claim 15, wherein mounting the plastic cap onto the substrate forms a cavity defined by the plastic cap and the substrate, the cavity being optically isolated from the first device.

20. The method of claim 15, further comprising mounting another electrical component over the substrate, wherein the another electrical component is enclosed by the plastic cap after mounting the plastic cap onto the substrate.
